(19) United States
(12) Patent Application Publication
(10) Pub. No.: US 2008/0150127 A1
(43) Pub. Date: Jun. 26, 2008

(54) Microelectronic package, method of manufacturing same, and system containing same

(76) Inventors: Nachiket Raravikar, Chandler, AZ (US); Leonel Arana, Phoenix, AZ (US); Daewoong Suh, Phoenix, AZ (US)

Correspondence Address: INTEL CORPORATION;c/o INTELLEVATE, LLC, P.O. BOX 52050, MINNEAPOLIS, MN, 55402, US

(21) Appl. No.: 11/644,683

(22) Filed: Dec. 21, 2006

(51) Int. Cl. H01L 23/36; H01L 21/58

(52) U.S. Cl. 257/712; 438/122; 257/E23.101; 257/E21.505

(57) ABSTRACT

A microelectronic package includes a substrate (110, 210, 310, 410, 510, 731), a die (120, 220, 320, 420, 520, 732), and a heat spreading region (130, 230, 330, 430, 530, 733). The die, which has an active side (121, 221, 321, 421, 521) and a passive side (122, 222, 322, 422, 522) located opposite the active side, is located over the substrate, and the heat spreading region is adjacent to the passive side of the die. The heat spreading region includes a composite (135, 235, 335, 435, 535) of nanotubes and a thermally conducting material.

### FIELD OF THE INVENTION

The disclosed embodiments of the invention relate generally to microelectronic packages, and relate more particularly to the removal of heat from microelectronic packages.

### BACKGROUND OF THE INVENTION

Microelectronic packages contain increasingly large numbers of microelectronic devices. Such devices generate heat during their operation, and as larger numbers of such devices are packed into smaller packages it becomes increasingly problematic to remove such heat. Heat spreaders Heat spreaders are one means of removing or otherwise addressing this heat before it can cause damage to the microelectronic system. An ideal heat spreader has high thermal conductivity and a coefficient of thermal expansion (CTE) that matches well with the CTE of the substrate or silicon and of the thermal interface material (TIM) with which the heat spreader may be associated. Copper, which is a typical material used in existing heat spreaders, has thermal conductivity and CTE values (approximately 400 Watts per meter-Kelvin (W/(m-K)) and approximately 17 parts per million per degree Celsius (ppm/° C.), respectively) that may not be adequate for the stringent thermo-mechanical demands of future microelectronic packages, yet the existing and proposed alternatives for package heat spreading are significantly more expensive than copper and offer no more than modest performance benefits. Proposed silver-diamond, aluminum-diamond, and other diamond-based composites, for example, may have a thermal conductivity of approximately 500-700 W/(m-K) and a CTE of approximately 4-7 ppm/° C. Such values may translate to mechanical advantages for diamond-based composites compared with copper due to the lower CTE of the former, yet the thermal benefits of the diamond-based composites are likely insignificant in comparison with copper, and their much higher cost makes them unattractive alternatives.

Package thermal modeling shows that one of the highest contributors to package thermal resistance is silicon itself. However, it is difficult to reduce the thermal resistance from silicon without degrading transistor performance. For example, thinning the silicon is one option to reduce the thermal resistance of silicon, yet this option creates problems such as silicon warpage and stress on the silicon during assembly, resulting in transistor performance degradation. Accordingly, there exists a need for a thermal spreading or other heat removal solution that offers significant performance advantages over existing materials at an acceptable cost.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a microelectronic package according to an embodiment of the invention;

FIG. 2 is a cross-sectional view of a different microelectronic package according to an embodiment of the invention;

FIG. 3 is a cross-sectional view of another microelectronic package according to an embodiment of the invention;

FIG. 4 is a cross-sectional view of a different microelectronic package according to an embodiment of the invention;

FIG. 5 is a cross-sectional view of another microelectronic package according to an embodiment of the invention;

FIG. 6 is a flowchart illustrating a method of manufacturing a microelectronic package according to an embodiment of the invention; and

FIG. 7 is a schematic diagram of a system that includes a microelectronic package according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a microelectronic package comprises a substrate, a die, and a heat spreading region. The die, which has an active side and a passive side located opposite the active side, is located over the substrate, and the heat spreading region is adjacent to the passive side of the die. The heat spreading region comprises a composite of nanotubes and a thermally conducting material. As further discussed below, these nanotube-based composite architectures have significantly higher thermal conductivity, lower thermal interface resistance, and lower CTE than known heat spreader materials.

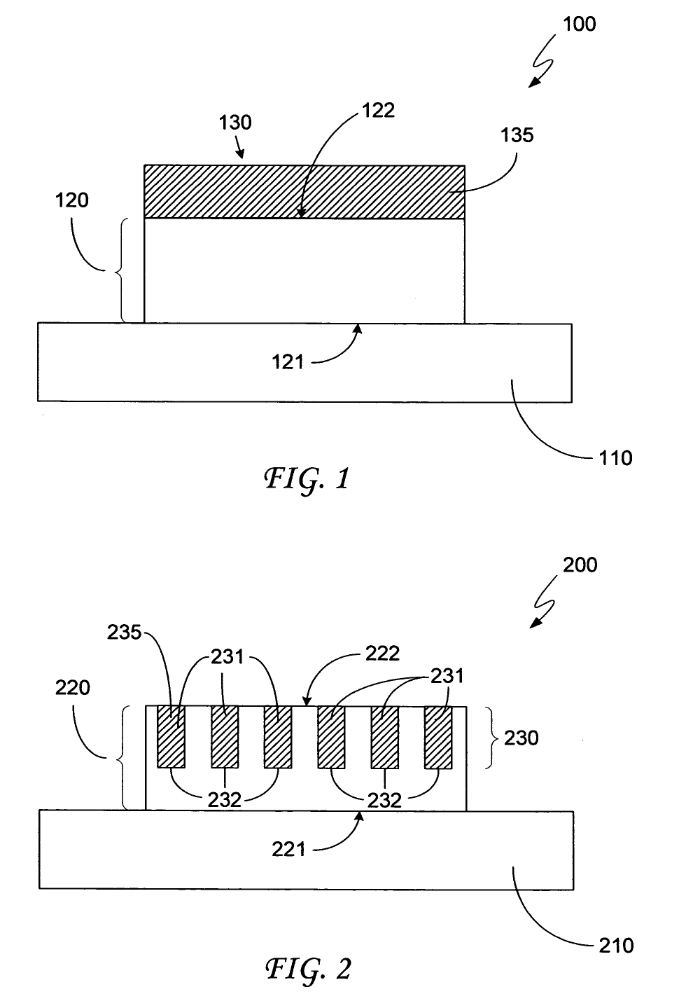

Referring now to the figures, FIG. 1 is a cross-sectional view of a microelectronic package 100 according to an embodiment of the invention. As illustrated in FIG. 1, microelectronic package 100 comprises a substrate 110 and a die 120 located over substrate 110. Die 120 is attached to substrate 110 using a method as known in the art, such as solder bumps (not shown) between die 120 and substrate 110. Die 120 has an active side 121 and an opposing passive side 122. Microelectronic package 100 further comprises a heat spreading region 130 adjacent to passive side 122 of die 120. Heat spreading region 130 comprises a composite 135 of nanotubes and a thermally conducting material and in the illustrated embodiment is formed directly on passive side 122 of die 120. As an example, heat spreading region 130 may be formed by electroplating a film or layer of composite 135 onto passive side 122.

As known in the art, nanotubes are elongated nanometer-scale tube-like structures that are frequently composed of carbon, though inorganic nanotubes made of materials such as boron nitride and silicon have been created as well. In one embodiment, the nanotubes are carbon nanotubes and the thermally conducting material is copper. Carbon nanotubes, having thermal conductivity of approximately 3000 W/(m-K), are very effective heat conductors, making them a strong candidate for use in heat spreading structures. Furthermore, with CTE values of approximately 0.5-1.0 ppm/° C., carbon nanotubes form a much closer CTE match to silicon than does copper or other existing heat spreader materials. Carbon nanotubes alone, however, have such high average thermal resistance—approximately 0.03 (° C.-cm²)/W—across the nanotube interface (lateral to the tube axis), as well as across the interface between the nanotube and an external surface (such as silicon or copper), that heat spreaders made of carbon nanotubes alone tend to merely scatter heat rather than transfer it efficiently. That tendency may potentially be overcome by combining the carbon nanotubes with copper or another thermally conducting material in a composite such as composite 135 in FIG. 1. As an example, for a package thermal resistance (R_{jc}) target of approximately 0.1° C.-cm²/W, the total nanotube thermal interface resistance needs to be less than approximately 0.025° C.-cm²/W, taking into account an equal (˜¼^{th}) contribution to R_{jc} from each of the bulk silicon, bulk nanotube TIMs, bulk Cu IHS, and various contact resistances between TIM-IHS as well as TIM-Si.

As mentioned above, copper has a thermal conductivity of approximately 400 W/(m-K) and a CTE of approximately 17 ppm/° C. When copper is combined with carbon nanotubes to form an embodiment of composite 135, the thermal conductivity and CTE of composite 135 are, respectively, at least approximately 1000 W/(m-K) and approximately 4 ppm/° C. or less. As may be seen, both values are significantly better than those available with copper alone. Furthermore, thermal interface resistances of composite 135 are likely to be significantly lower than thermal interface resistances of existing heat spreader materials, meaning environmental heat may be transferred into the heat-conducting carbon nanotubes much more efficiently in the stated embodiment of composite 135 than would be possible in existing heat spreader materials. One explanation for the increased heat transfer efficiency of composite 135 may be that in composite 135 the carbon nanotubes and the copper are mixed together in a continuous matrix in which the carbon nanotubes are substantially surrounded on all sides by copper and that is characterized by an absence or scarcity of air pockets that, if present, would likely prevent or inhibit the heat transfer. As an example, such a matrix may be achieved using an electroplating process or the like.

FIG. 2 is a cross-sectional view of a microelectronic package 200 according to an embodiment of the invention. As illustrated in FIG. 2, microelectronic package 200 comprises a substrate 210 and a die 220 located over substrate 210. The means of attachment between die 220 and substrate 210 is not explicitly illustrated in FIG. 2, but may be accomplished according to methods known in the art. Die 220 has an active side 221 and an opposing passive side 222. Microelectronic package 200 further comprises a heat spreading region 230 adjacent to passive side 222 of die 220. Heat spreading region 230 comprises a composite 235 of nanotubes and a thermally conducting material. As an example, composite 235 can be similar to composite 135, shown in FIG. 1.

Heat spreading region 230 comprises a plug 231 formed from composite 235 and recessed into passive side 222 of die 220 and extending toward active side 221 of die 220. In the embodiment illustrated in FIG. 2, heat spreading region 230 comprises a plurality of plugs 231, each of which are formed from composite 235. In one embodiment, plugs 231 are located inside vias 232 that may be lined with a metal such as gold, nickel, titanium, or the like so as to enhance adhesion between composite 235 and the sidewalls of vias 232. (Such metal linings are not illustrated in FIG. 2.) Plugs 231 may facilitate the efficient transfer of heat away from active side 221 of die 220 and may thereby reduce the thermal resistance contribution of die 220 to microelectronic package 200. The use of composite 235 will, moreover, reduce the significance of mechanical stresses since composite 235 has a CTE closely matching that of die 220. Such reduction in mechanical stresses may also be a feature of other microelectronic packages described herein, including perhaps microelectronic package 100 as well as those to be introduced and discussed below.

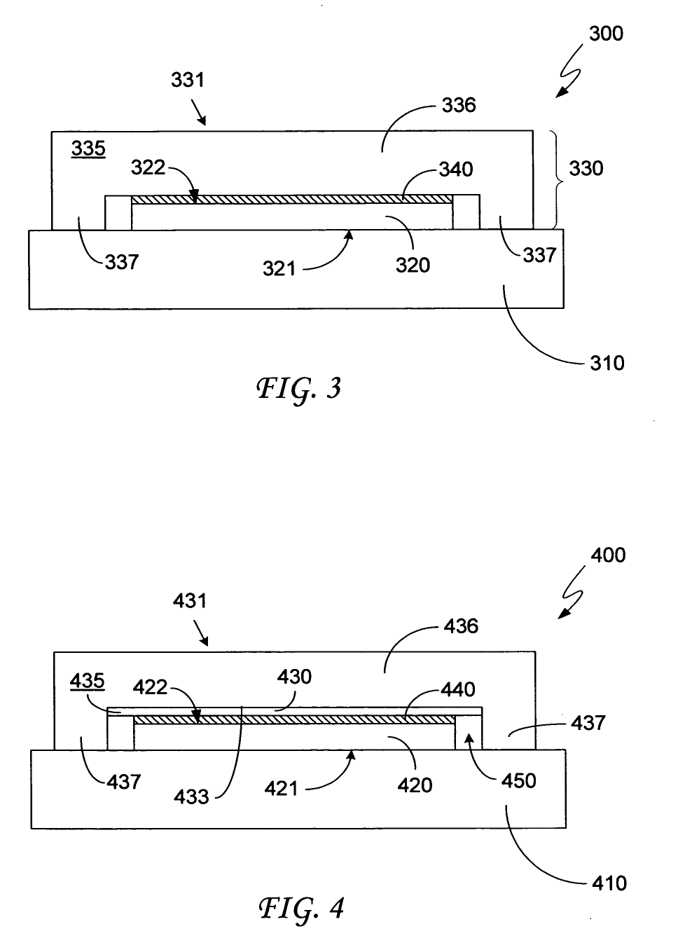

FIG. 3 is a cross-sectional view of a microelectronic package 300 according to an embodiment of the invention. As illustrated in FIG. 3, microelectronic package 300 comprises a substrate 310 and a die 320 located over substrate 310. The means of attachment between die 320 and substrate 310 is not explicitly illustrated in FIG. 3, but may be accomplished according to methods known in the art. Die 320 has an active side 321 and an opposing passive side 322. Microelectronic package 300 further comprises a heat spreading region 330 adjacent to passive side 322 of die 320. Heat spreading region 330 comprises a composite 335 of nanotubes and a thermally conducting material. As an example, composite 335 can be similar to composite 135, shown in FIG. 1.

Heat spreading region 330 comprises an integrated heat spreader 331 formed from composite 335. A thermal interface material (TIM) 340 lies between integrated heat spreader 331 and die 320 and may increase thermal transfer efficiency between die 320 and integrated heat spreader 331. Integrated heat spreader 331 has a body 336 and lips 337, and may further comprise an air inlet (not shown) that may be located in body 336 or lips 337. In non-illustrated embodiments, body 336 and lips 337 may have relative sizes and/or positioning different from what is shown in FIG. 3. As an example, the air inlet may be a hole or other opening in body 336 or lips 337.

FIG. 4 is a cross-sectional view of a microelectronic package 400 according to an embodiment of the invention. As illustrated in FIG. 4, microelectronic package 400 comprises a substrate 410 and a die 420 located over substrate 410. The means of attachment between die 420 and substrate 410 is not explicitly illustrated in FIG. 4, but may be accomplished according to methods known in the art. Die 420 has an active side 421 and an opposing passive side 422. Microelectronic package 400 further comprises a heat spreading region 430 adjacent to passive side 422 of die 420. Heat spreading region 430 comprises a composite 435 of nanotubes and a thermally conducting material. As an example, composite 435 can be similar to composite 135, shown in FIG. 1.

In the embodiment illustrated in FIG. 4, heat spreading region 430 is a heat spreading layer formed from composite 435 and forming a part of an integrated heat spreader 431 that comprises a body 436 and lips 437. As an example, integrated heat spreader 431 can be made of copper or the like, or may have a copper core. A thermal interface material (TIM) 440 lies between, and may increase thermal transfer efficiency between, integrated heat spreader 431 and die 420. In a non-illustrated embodiment, integrated heat spreader 431 further comprises an air inlet (not shown) that may be similar to the air inlet described in connection with FIG. 3. As an example, integrated heat spreader 431 can be similar to integrated heat spreader 331, also shown in FIG. 3. As another example, the heat spreading layer can be plated over or otherwise attached to at least a portion 433 of integrated heat spreader 431.

In the illustrated embodiment, integrated heat spreader 431 comprises a cavity 450 capable of receiving at least a portion of die 420, and portion 433 of integrated heat spreader 431 is in cavity 450. The effect is that heat spreading region 430 is located close to die 420 and helps to efficiently transfer heat away therefrom.

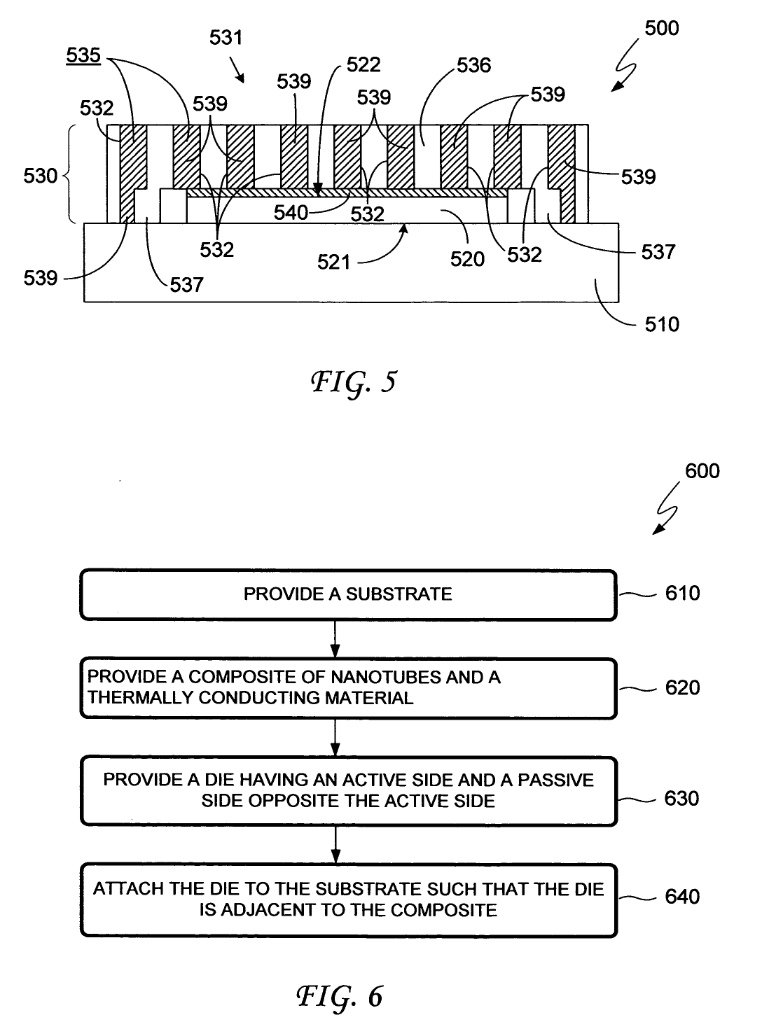

FIG. 5 is a cross-sectional view of a microelectronic package 500 according to an embodiment of the invention. As illustrated in FIG. 5, microelectronic package 500 comprises a substrate 510 and a die 520 located over substrate 510. The means of attachment between die 520 and substrate 510 is not explicitly illustrated in FIG. 5, but may be accomplished according to methods known in the art. Die 520 has an active side 521 and an opposing passive side 522. Microelectronic package 500 further comprises a heat spreading region 530 adjacent to passive side 522 of die 520. Heat spreading region 530 comprises a composite 535 of nanotubes and a thermally conducting material. As an example, composite 535 can be similar to composite 135, shown in FIG. 1.

Heat spreading region 530 comprises a plug 539 formed from composite 535 and recessed into an integrated heat spreader 531. Integrated heat spreader 531 comprises a body 536 and lips 537. As an example, integrated heat spreader 531 can be made of copper or the like, or may have a copper core. A thermal interface material (TIM) 540 lies between, and may increase thermal transfer efficiency between, integrated heat spreader 531 and die 520. In a non-illustrated embodiment, integrated heat spreader 531 further comprises an air inlet (not shown) that may be similar to the air inlet described in connection with FIG. 3. As an example, integrated heat spreader 531 can be similar to integrated heat spreader 331, also shown in FIG. 3.

In the embodiment illustrated in FIG. 5, heat spreading region 530 comprises a plurality of plugs 539, each of which are formed from composite 535. In one embodiment, plugs 539 are located inside vias 532 that have been etched, drilled, or otherwise formed in integrated heat spreader 531.

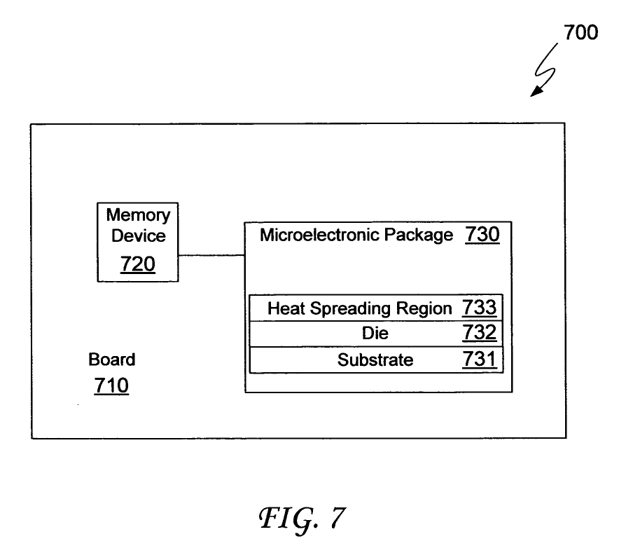

FIG. 6 is a flowchart illustrating a method 600 of manufacturing a microelectronic package according to an embodiment of the invention. A step 610 of method 600 is to provide a substrate. As an example, the substrate can be similar to substrates 110, 210, 310, 410, or 510, shown respectively in FIGS. 1, 2, 3, 4, and 5.

A step 620 of method 600 is to provide a composite of nanotubes and a thermally conducting material. As an example, the composite can be similar to composites 135, 235, 335, 435, or 535, shown respectively in FIGS. 1, 2, 3, 4, and 5. Accordingly, in at least one embodiment, the nanotubes are carbon nanotubes and the thermally conducting material is or comprises copper such that step 620 comprises providing a matrix or other composite comprising carbon nanotubes and copper. As an example, a film of the composite may be created by electroplating carbon nanotubes and copper together onto a cathode from solution.

In the same or another embodiment, step 620 comprises providing an integrated heat spreader formed from the composite. As an example, the integrated heat spreader can be similar to integrated heat spreaders 331, 431, or 531, shown respectively in FIGS. 3, 4, and 5. In one embodiment, providing the integrated heat spreader can comprise making the integrated heat spreader out of the composite. In another embodiment, providing the integrated heat spreader can comprise forming the integrated heat spreader into a desired shape and electrodepositing (i.e., forming via electrodeposition or other electroplating process) the composite onto or into the integrated heat spreader or a portion thereof.

The formation of the integrated heat spreader into the desired shape may be accomplished in various ways such as, for example, by joining together discrete electroplated sections, as by brazing, welding, or the like, by reshaping or otherwise forming an electroplated slab, by subtracting portions of an electroplated slab, as by etching, machining, or the like, or by various combinations of these or similar procedures. As another example, the integrated heat spreader may be formed by an electroforming process in which the composite is electroplated onto a pre-fabricated mold negatively replicating the final shape. It will be understood by one of ordinary skill in the art that the formation and electrodeposition processes may be performed in either order, as the circumstances dictate, such that in the final example of those given above the formation process precedes the electrodeposition process, while in the former examples the electrodeposition process precedes the formation process.

In one embodiment, step 620 comprises providing an integrated heat spreader, forming a cavity in the integrated heat spreader, and plating a layer formed from the composite in the cavity. As an example, the cavity may be formed by an etching operation, a drilling operation, or the like, and can be similar to cavity 450 shown in FIG. 4. As another example, the composite layer may be formed in the cavity by placing a copper integrated heat spreader in an electrolyte bath, masking the integrated heat spreader such that only the cavity is exposed, and using the integrated heat spreader as the cathode during the electroplating process.

In a different embodiment, step 620 does not involve the provision or manipulation of an integrated heat spreader, and instead comprises plating the composite onto the passive side of the die itself. In yet another embodiment, step 620 comprises forming (as by drilling, etching, or the like) a cavity in the passive side of the die, conformally or otherwise depositing a metal layer in the cavity, and electrodepositing or otherwise depositing the composite in the cavity adjacent to the metal layer. As an example, the cavity can be similar to via 232 and the deposited composite can be similar to plug 231, both of which are shown in FIG. 2. Multiple vias and plugs may be formed if desired, as illustrated in FIG. 2.

A step 630 of method 600 is to provide a die having an active side and a passive side opposite the active side. As an example, the die can be similar to dies 120, 220, 320, 420, or 520, shown respectively in FIGS. 1, 2, 3, 4, and 5. A step 640 of method 600 is to attach the die to the substrate such that the die is adjacent to the composite.

FIG. 7 is a schematic diagram of a system 700 that includes a microelectronic package according to an embodiment of the invention. As further discussed below, the microelectronic package can be similar to one or more of the microelectronic packages described above, or to combinations thereof. As illustrated in FIG. 7, system 700 comprises a board 710, a memory device 720 disposed on board 710, and a microelectronic package 730 disposed on board 710 and coupled to memory device 720. Microelectronic package 730 comprises a substrate 731, a die 732 located over substrate 731 and having an active side and an opposing passive side, and a heat spreading region 733 adjacent to the passive side of die 732 and comprising a composite of nanotubes and a thermally conducting material. As an example, microelectronic package 730 can be similar to microelectronic packages 100, 200, 300, 400, or 500, shown respectively in FIGS. 1, 2, 3, 4, and 5. Similarly, die 732 can be similar to dies 120, 220, 320, 420, or 520, shown respectively in FIGS. 1, 2, 3, 4, and 5, heat spreading region 733 can be similar to heat spreading regions 130, 230, 330, 430, or 530, also shown respectively in FIGS. 1, 2, 3, 4, and 5, and the composite can be similar to composites 135, 235, 335, 435, or 535, shown respectively in FIGS. 1, 2, 3, 4, and 5. Accordingly, in various embodiments, the heat spreading region comprises an integrated heat spreader having at least a portion that comprises the composite. As described above, the integrated heat spreader, where it forms a part of the microelectronic package, may be made out of the composite, may have one or more plugs made out of the composite recessed or otherwise integrated therein, may have a film or other layer made out of the composite plated thereon or otherwise associated therewith, or the like.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic package and related methods and systems discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A microelectronic package comprising:
a substrate;
a die located over the substrate and having an active side and a passive side opposite the active side; and
a heat spreading region adjacent to the passive side of the die and comprising a composite of nanotubes and a thermally conducting material.

2. The microelectronic package of claim 1 wherein:
the nanotubes are carbon nanotubes.

3. The microelectronic package of claim 1 wherein:
the thermally conducting material is copper.

4. The microelectronic package of claim 1 wherein:
the heat spreading region comprises an integrated heat spreader formed from the composite.

5. The microelectronic package of claim 1 wherein:
the heat spreading region comprises an integrated heat spreader having a heat spreading layer formed from the composite attached to at least a first portion thereof.

6. The microelectronic package of claim 5 wherein:
the integrated heat spreader comprises a cavity capable of receiving at least a portion of the die; and
the first portion of the integrated heat spreader is in the cavity.

7. The microelectronic package of claim 1 further comprising:
an integrated heat spreader over the die,
wherein:
the heat spreading region comprises a plug formed from the composite and forming a part of the integrated heat spreader.

8. The microelectronic package of claim 1 wherein:
the heat spreading region comprises a film located on the passive side of the die.

9. The microelectronic package of claim 1 wherein:
the heat spreading region comprises a plug formed from the composite; and
the plug is recessed into the passive side of the die.

10. A method of manufacturing a microelectronic package, the method comprising:
providing a substrate;
providing a composite of nanotubes and a thermally conducting material;
providing a die having an active side and a passive side opposite the active side; and
attaching the die to the substrate such that the die is adjacent to the composite.

11. The method of claim 10 wherein:
providing the composite comprises providing a matrix comprising carbon nanotubes and copper.

12. The method of claim 11 wherein:
providing the composite comprises providing an integrated heat spreader formed from the composite.

13. The method of claim 12 wherein:
providing the integrated heat spreader comprises:
forming the integrated heat spreader into a desired shape; and
electrodepositing the composite onto the integrated heat spreader.

14. The method of claim 11 wherein:
providing the composite comprises:
providing an integrated heat spreader having a copper core; and
plating the composite over at least a portion of the copper core.

15. The method of claim 11 wherein:
providing the composite comprises:
providing an integrated heat spreader;
forming a cavity in the integrated heat spreader; and
plating a layer formed from the composite in the cavity.

16. The method of claim 11 wherein:
providing the composite comprises plating the composite onto the passive side of the die.

17. The method of claim 11 wherein:
providing the composite comprises forming a cavity in the passive side of the die;
depositing a metal layer in the cavity; and
depositing the composite in the cavity adjacent to the metal layer.

18. A system comprising:
a board;
a memory device disposed on the board; and
a microelectronic package disposed on the board and coupled to the memory device,
wherein:
the microelectronic package comprises:
a substrate;
a die located over the substrate and having an active side and a passive side opposite the active side; and
a heat spreading region adjacent to the passive side of the die and comprising a composite of nanotubes and a thermally conducting material.

19. The system of claim 18 wherein:
the nanotubes are carbon nanotubes; and
the thermally conducting material is copper.

20. The system of claim 19 further comprising:
an integrated heat spreader having at least a portion that comprises the composite.
